(19) United States
(12) Patent Application Publication
(10) Pub. No.: US 2025/0336625 A1
(43) Pub. Date: Oct. 30, 2025

(54) LOAD CONTROL DEVICE AND RELATED ASSEMBLY METHOD

(71) Applicant: Chengli LI, Suzhou (CN)

(72) Inventor: Wensen CHEN, Suzhou (CN)

(73) Assignee: Chengli LI, Suzhou (CN)

(21) Appl. No.: 19/005,367

(22) Filed: Dec. 30, 2024

(30) Foreign Application Priority Data
Apr. 26, 2024 (CN) 202410516688.2

(51) Int. Cl. H01H 23/08; H01H 11/04; H01H 23/04; H01H 23/16

(52) U.S. Cl. CPC H01H 23/08; H01H 11/04; H01H 23/04; H01H 23/16

(57) ABSTRACT

An electrical load control device and an assembly method thereof. The load control device includes a base block and a first operating component arranged on the base block for adjusting an operation parameter of an electrical load. The base block has a slide groove and an operating through hole, and the first end of the slide groove can be selectively opened to connect the slide groove with the operating through hole. The first operating component includes a slider, which is slidably engaged with the slide groove. When the slide groove is connected with the operating through hole, the slider can be assembled with the slide groove through the operating through hole, without requiring the slider to be pressed through the groove. The structure and assembly method of the load control device reduce assembly difficulty, avoid deformation or wear, increase device service life, and provides a wider slider for easy operation.

### BACKGROUND OF THE INVENTION

The present invention relates generally to an electrical load control device, and more particularly, to an electrical load control device and an assembly method of the load control device.

Currently, in electrical load control devices commonly seen in the market, such as sliding dimmers, the slider is typically assembled using interference fit. FIG. 1 shows an American standard toggle switch with sliding dimmer 100, which includes a toggle switch 102, a slider 104 and a slide groove 106. The width of the head of the slider 104 is slightly larger than the width of the slide groove 106. During assembly, the head of the slider 104 squeezes the inner walls on both sides of the slide groove 106 to open the slide groove, so that the head of the slider may be inserted from the bottom of the slide groove. When the head of the slider is inserted to the preset position, the inner walls on both sides of the slide groove rebound to the original width to limit the slider, and the slider will not fall out of the slide groove under normal circumstances.

However, this interference fitted sliding adjustment device has the following technical problems: a large force needs to be applied to cause a certain deformation of the slide groove, which makes assembly difficult; when the slider squeezes the inner wall of the slide groove, the material will be deformed due to the force, affecting the life of the material; the slider may be worn during the pressing process; since the slide groove is a through hole, the outside and inside of the device are connected through the slide groove, affecting the safety performance of the device; due to the limitation of the width of the slide groove, the width of the slider is small, which makes it inconvenient for users to operate.

### SUMMARY OF THE INVENTION

To solve at least some of the above technical problems, embodiments of the present invention provide an electrical load control device and an assembly method of the electrical load control device. The load control device is provided with a slide groove and an operating through hole on the base block selectively connected to each other, so that the slider may be assembled to the slide groove through the operating through hole, which reduces the assembly difficulty of the device, avoids deformation of the material during the assembly process, improves the service life of the material, avoids wear of the slider; reduces the restriction of the slide groove width on the slider, and may reasonably increase the slider width for user operation.

Based on this, an electrical load control device is proposed in the first aspect of the present disclosure, which includes a base block, and a first operating component, which is arranged on the base block and is configured to adjust a first operation parameter of an electrical load; wherein the base block is provided with a slide groove and an operating through hole, and the first end of the slide groove may be selectively opened to connect the slide groove with the operating through hole; wherein the base block includes a slide groove and an operating through hole, wherein a first end of the slide groove is selectively opened to connect the slide groove with the operating through hole, wherein the first operating component includes a slider, slidably engaged with the slide groove, wherein when the slide groove is connected with the operating through hole, the slider is moveable from the operating through hole to the slide groove to assemble the slider in the slide groove.

In some embodiments, the load control device further includes: a stopper, detachably connected to the base block, configured to block the first end of the slide groove and the operating through hole.

In some embodiments, the stopper includes: an upright portion, configured to block the first end of the slide groove; and a transverse portion, connected to the upright portion and arranged at an angle relative to the upright portion, configured to block the operating through hole.

In some embodiments, the transverse portion includes contactable areas configured to provide operating positions for handling the stopper during assembly.

In some embodiments, the slide groove includes a first slide rail and a second slide rail, respectively arranged at different heights; wherein the slider has an S shape, and includes a first notch and a second notch arranged at different heights and opposite to each other, wherein the first notch is configured to cooperate with the first slide rail and the second notch is configured to cooperate with the second slide rail.

In some embodiments, the first operating component further includes a sliding rheostat, wherein a lower end of the slider includes a third notch configured to cooperate with a sliding piece of the sliding rheostat.

In some embodiments, the base block includes protruding sidewalls extending upwardly, wherein the slide groove is a semi-enclosed first operating slot formed on one side of one protruding sidewalls.

In some embodiments, the protruding sidewalls form a fully enclosed second operating slot located adjacent to the first operating slot; wherein the load control device further comprises a second operating component, disposed in the second operating slot and configured to control a second operation parameter of the electrical load.

In some embodiments, the load control device further includes: a cover plate, the cover plate defining an opening, wherein the cover plate covers the base block and fully closes the first operating slot by an edge of the opening.

In another aspect, the invention provides an assembly method for assembling a load control device, which includes: providing a base block, the base block including a semi-enclosed first operating slot and an operating through hole, a first slide rail and a second slide rail adjacent the first operating slot, wherein a first end of the first operating slot is open so that the first operating slot is connected to the operating through hole; providing a slider, the slider including a first notch and a second notch; inserting the slider into the operating through hole and aligning the first notch and the second notch respectively with ends of the first slide rail and the second slide rail; and sliding the slider into the first operating slot, wherein the slider is in sliding engagement with and is slidable along the first slide rail and the second slide rail.

In some embodiments, the method further includes providing a stopper, the stopper including an upright portion and a transverse portion, and positioning the stopper to block the first end of the first operating slot and the operating through hole, wherein the upright portion blocks the first end of the first operating slot and the transverse portion blocks the operating through hole.

In some embodiments, the method further includes providing a cover plate, wherein the cover plate defines an opening, and covering the base block with the cover plate to completely close the first operating slot by an edge of the opening.

Embodiments of the present invention provide a selectively connected slide groove and an operating through hole on the seat of the load control device, so that the slider can be installed through the operating through hole, thereby reducing the difficulty of product installation, avoiding deformation of materials during the installation process and increasing the service life of the material, avoiding wear of the slider, reducing the restriction of the slide groove width on the slider width, and reasonably increasing the slider width for user operation.

### BRIEF DESCRIPTION OF DRAWINGS

Preferred embodiments of the present invention are described with reference to the drawings. Other features and advantages of the present invention may be understood from the embodiments described below with reference to the drawings.

FIG. 1 illustrates a conventional sliding dimmer 100 that uses an interference fit assembly method.

FIG. 2A illustrates a load control device 200 according to an embodiment of the present invention.

FIG. 2B is a cross-sectional view of the load control device 200 of FIG. 2A taken along section A-A.

FIG. 2C is a cross-sectional view of the load control device 200 of FIG. 2A taken along section B-B.

FIG. 2D is an exploded view of the load control device 200 of FIG. 2A.

FIG. 2E illustrates the structure of a portion of the load control device 200 of FIG. 2A.

FIG. 2F illustrates the structure of the slider 204 of the load control device 200 of FIG. 2A.

FIG. 2G illustrates the structure of the slider 204 of FIG. 2F from another viewing angle.

FIG. 2H is a cross-sectional view of the slider 204 of FIG. 2G taken along section C-C.

FIG. 2I illustrates the structure of the load control device 200 during assembly, before the stopper 206 is assembled (when the slide groove 2022 and operating through hole 2024 are connected) and after it is assembled (when the operating through hole 2024 is blocked).

FIG. 2J illustrates the stopper of the load control device 200 and its handling surfaces.

FIG. 3 is a flow chart showing an assembly method 300 of the load control device 200.

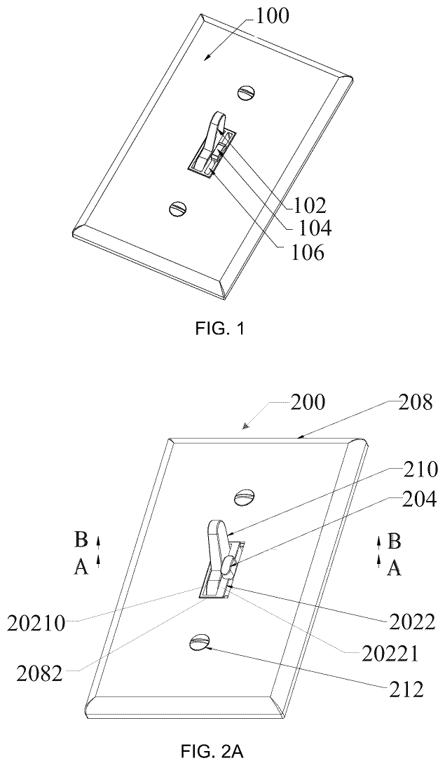

### DETAILED DESCRIPTION OF THE INVENTION

Preferred embodiments of the present invention are described below with reference to the drawings. These drawings and descriptions explain embodiments of the invention but do not limit the invention. The described embodiments are not all possible embodiments of the present invention. Other embodiments are possible without departing from the spirit and scope of the invention, and the structure and/or logic of the illustrated embodiments may be modified. Thus, it is intended that the scope of the invention is defined by the appended claims.

Before describing the embodiments, some terms used in this disclosure are defined here to help the reader better understand this disclosure.

In the descriptions below, terms such as “one,” “one group,” etc. do not limit the number of components, but means at least one. In the descriptions below, terms such as “including” are intended to be open-ended and mean “including without limitation”, and may include other contents. “Based on” means “at least partly based on.” “An embodiment” means “at least one embodiment.” “Another embodiment” means “at least another embodiment,” etc. In this disclosure, the above terms do not necessarily refer to the same embodiments. Further, the various features, structures, materials or characteristics may be suitably combined in any of the one or more embodiments. Those of ordinary skill in the art may combine the various embodiments and various characteristics of the embodiments described herein when they are not contrary to each other.

As discussed above, in order to solve at least some of the technical problems existing in the interference fit assembly structure and assembly method of conventional load control devices, embodiments of the present invention provide an improved load control device. The descriptions below use a sliding dimmer as an example, but it should be noted that the present invention is not limited to sliding dimmers, but may also be used for any other devices for which the principles of the invention are applicable, including load control devices such as speed regulators.

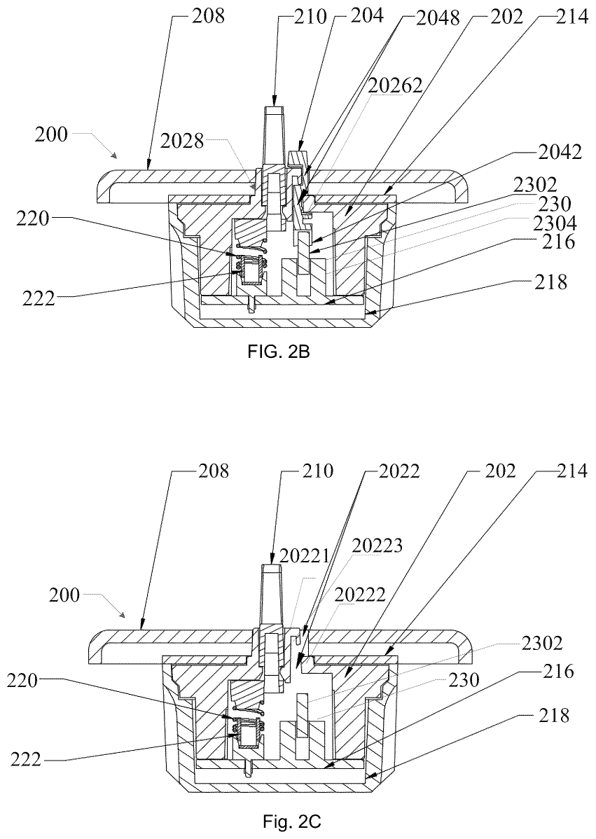

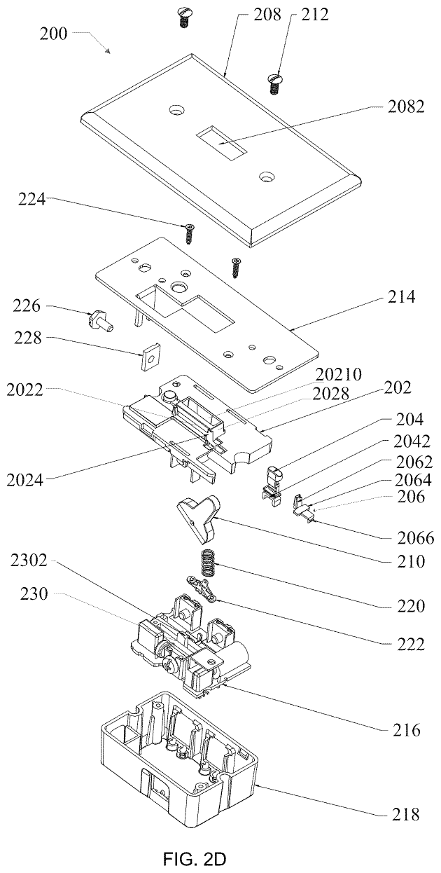

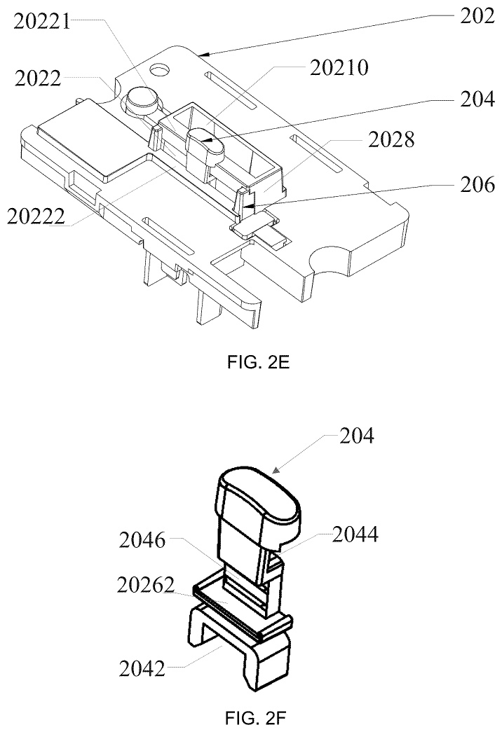

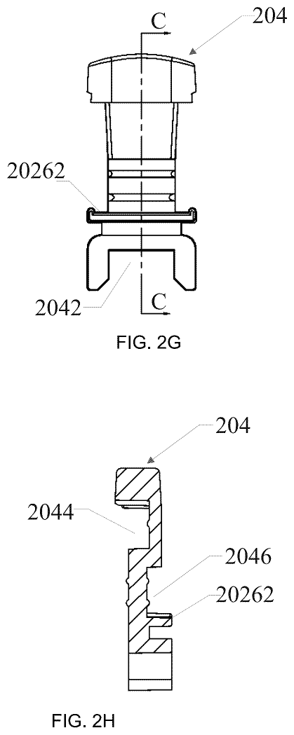

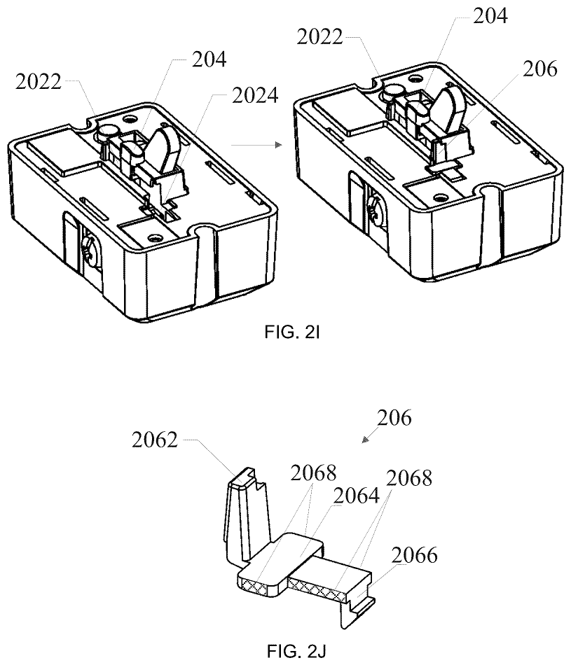

As shown in FIGS. 2A to 2J, an embodiment of the present invention provides an electrical load control device 200 which includes a base block 202 (face cover) and a first operating component. The base block 202 is provided with a slide groove 2022 and an operating through hole 2024, and the first operating component includes a slider 204. The first operating component is disposed on the base block 202, and is configured to adjust a first operation parameter of an electrical load, such as the illumination of a lamp, the speed of a motor, and the like. The slide groove 2022 extends horizontally, and the operating through hole 2024 extends vertically and is open to the top of the base clock 202. The first end of the slide groove 2022 may be selectively opened or closed to allow the slide groove 2022 to communicate with the operating through hole 2024. When the first end of the slide groove 2022 is selectively opened, the slide groove 2022 is connected with the operating through hole 2024, and the slider 204 may be assembled with the slide groove 2022 through the operating through hole 2024. More specifically, the slider 204 is inserted vertically into the operating through hole 2024, and then slid horizontally from the operating through hole 2024 into the slide groove 2022. When the first end of the slide groove 2022 is selectively closed, the slide groove 2022 is not connected to the operating through hole 2024, and the operating through hole 2024 and the first end of the slide groove 2022 are blocked.

In some embodiments, the load control device 200 further includes a stopper 206. The stopper 206 is detachably connected to the base block 202, and is used to block the first end of the slide groove 2022 (i.e., the end that may be selectively opened to connect with the operating through hole) and the operating through hole 2024. The slider 204 may be limited in the slide groove 2022. In some embodiments, the stopper 206 includes an upright portion 2062 and a transverse portion 2064; the upright portion 2062 is used to block the first end of the slide groove 2022, and the transverse portion 2064 is connected to the upright portion 2062 and is arranged at an angle relative to the upright portion 2062 to block the operating through hole 2024. In some embodiments, the upright portion 2062 is located at the end of the transverse portion 2064 and extends upwardly perpendicular to the transverse portion 2064.

FIG. 21 shows the partial structure of the load control device 200 before and after the stopper 206 is assembled during the assembly process. The left side of the figure shows the structure before the stopper 206 is assembled, when the slide groove 2022 is connected to the operating through hole 2024. The right side of the figure shows the structure after the stopper 206 is assembled, when the slide groove 2022 is not connected to the operating through hole 2024, and the stopper 206 blocks the first end of the slide groove and the operating through hole. This assembly structure has the advantage of being easy to assemble and disassemble. Compared with interference fit assembling, it does not require a large force to assemble and disassemble. The stopper 206 may limit the sliding path of the slider 204. In addition, by reasonably designing the size of the operating through hole and the slider, the slider may be assembled without compression, avoiding deformation and wear of the material, which improves the service life of the device.

In some embodiment, the slider 204 includes a first section and a second section. When the slider 204 is inserted vertically into the operating through hole 2024 and is aligned with the first end of the slide groove 2022, the first section is located above the operating through hole 2024, and the second section is located below the operating through hole 2024; the length and width of the operating through hole are not less than the length and width of at least one of the first section and the second section. When the length and width of the operating through hole are not less than the length and width of the first section, the slider may be inserted into the operating through hole from the bottom up; when the length and width of the operating through hole are not less than the length and width of the second section, the slider may be inserted into the operating through hole from the top down; when the length and width of the operating through hole are not less than the overall length and width of the slider, the slider may be inserted into the operating through hole from the top down or from the bottom up, and the assembly method is more flexible.

In some embodiments, the stopper 206 is a separate component, an integrally formed structure, and the upright portion 2062 and the transverse portion 2064 are two parts of the single component with different functions. During assembly, the functions of the upright portion 2062 and the transverse portion 2064 may be realized by a one-step assembly operation of the stopper 206. In other embodiments, the stopper 206 may be a combined component, which may include two sub-components, the upright portion 2062 and the transverse portion 2064. During assembly, it is necessary to operate the upright portion 2062 and the transverse portion 2064 separately to realize the assembly of the upright portion 2062 and the transverse portion 2064 in multiple steps, which may be to assemble the upright portion 2062 first and then the transverse portion 2064; or to assemble the transverse portion 2064 first and then the upright portion 2062.

As shown in FIG. 2J, in some embodiments, the transverse portion 2064 has contactable areas (handling surfaces) 2068 for providing operating positions for grabbing during assembly. The contactable area 2068 may be located on both sides of the transverse portion 2064, as shown in the hatched area in the figure, and the user acts on the area to grab and assemble the stopper 206, which is convenient for the user to operate and improves assembly efficiency.

Optionally, the detachable connection structure between the stopper 206 and the base block 202 may be a snap connection structure, a threaded connection structure or an interference connection structure, etc. Preferably, the stopper 206 and the base block 202 use a snap connection structure, which has the advantages of simple structure, convenient assembly, and the material is not easy to deform and wear. In some embodiments, the stopper 206 includes a connecting portion 2066, which is used to accomplish the detachable connection between the stopper 206 and the base block 202. The connecting portion 2066 is connected to the transverse portion 2064 and is arranged at an angle relative to the transverse portion 2064. In some embodiments, the connecting portion 2066 and the upright portion 2062 are respectively arranged at both ends of the transverse portion 2064 and extend in opposite directions respectively, e.g., the upright portion 2062 extends upwardly perpendicularly to the transverse portion 2064, and the connecting portion 2066 extends downward perpendicularly to the transverse portion 2064. In some embodiments, the lower end of the connecting portion 2066 is a hook-shaped structure.

In some embodiments, as shown in FIGS. 2B, 2C and 2D, the slide groove 2022 has a first slide rail 20221 and a second slide rail 20222, which are respectively arranged at different heights, one high and one low. Correspondingly (see FIGS. 2F and 2H), the slider 204 has a first notch (groove) 2044 and a second notch (groove) 2046, which are respectively arranged at different heights, one high and one low, and opposite to each other, wherein the first notch 2044 cooperates with the first slide rail 20221, and the second notch 2046 cooperates with the second slide rail 20222. The cross section of the slider 204 is arranged in an S shape, and the slider 204 has an S structure 2048. Correspondingly, the slide groove 2022 also has an S shaped channel for the slider 204 to slidingly cooperate with. In other embodiments, the slider 204 may have only the first notch 2044, and the first notch 2044 cooperates with the first slide rail 20221 of the slide groove, so that the slider slides in the slide groove. The slider having only the first notch has a simpler structure, while the slider having both the first notch and the second notch has a stronger sliding stability.

In some embodiments (sec FIGS. 2F, 2G and 2H), a support portion 20262 extends outward from the bottom of the second notch 2046, which improves the stability of the sliding fit between the slider and the slide groove and improving user experience during the sliding adjustment process. In some embodiments, the side of the slide groove includes a gap structure 20223 (FIG. 2C), and the design of the gap structure 20223 improves the production process, improving the surface flatness of the final product, facilitating the sliding adjustment of the slider on the side surface, and improving user experience.

In some embodiments, the first slide rail 20221 and the second slide rail 20222 of the slide groove 2022 have very little or no gap between them in the horizontal direction. The situation where there is no gap in the horizontal direction includes the two slide rails being connected in the horizontal direction, or partially overlapping in the horizontal direction. The specific structure may be adjusted according to the requirements of the device safety performance in the application scenario. The structure in which the first slide rail 20221 and the second slide rail 20222 have very little or no gap in the horizontal direction can help to achieve isolation between the interior and exterior of the device. Compared with the interference fit load control device in the conventional device (the gap in the slide groove of the interference fit structure has a large width, which is not conducive to the isolation between the interior and exterior of the device), the present disclosure may effectively prevent external dust and other impurities from entering the interior of the device, which improves the safety performance of the device.

In some embodiments, taking the resistive load control device as an example, the first operating component further includes a sliding rheostat 230. The sliding rheostat 230 includes a sliding piece 2302 and a main body 2304. The lower end of the slider 204 is provided with a third notch 2042, which cooperates with the sliding piece 2302 of the sliding rheostat 230. When the slider slides in the slide groove, the sliding piece 2302 of the sliding rheostat is driven to slide on the main body 2304, thereby adjusting the first operation parameter of the electrical load.

In some other embodiments, taking a voltage load control device as an example, the first operating component further includes a transformer (not shown). The slider 204 is coupled to the transformer, and the voltage of the load is changed by adjusting the contact position between the brush of the transformer and the coil wound outside the transformer yoke.

In some embodiments, the base block 202 is provided with protruding sidewalls 2028 that extend upwardly from the rest of the base block. One side of one protruding sidewall 2028 is provided with a semi-enclosed first operating slot, which is the slide groove 2022. As shown in FIGS. 2C and 2E, on one side of the first operating slot 2022 (in FIG. 2C, the left side) is the first slide rail 20221 (formed by a part of the sidewall) at a higher position, and on the other side of it (in FIG. 2C, the right side) is the second slide rail 20222 (not a part of the sidewall) at a lower position. Due to the height difference between the first slide rail 20221 and the second slide rail 20222, the first operating slot 2022 is in a semi-enclosed state, that is, the side where the second slide rail 20222 is located (in FIG. 2C, the left side) is not enclosed.

In some embodiments, the protruding sidewalls 2028 form a fully enclosed second operating slot 20210 located adjacent to the first operating slot 2022. The load control device 200 further includes a second operating component 210, which is disposed in the second operating slot 20210 and is used to control a second operation parameter of the electrical load. For example, when the second operating component 210 is a toggle switch, it may be used to control the on and off of the load.

In some embodiments, the load control device 200 further includes a cover plate (faceplate) 208. The cover plate 208 is provided with an opening 2082. The cover plate 208 covers the base block 202 and fully closes the first operating slot 2022 by the edge of the opening 2082. As shown in FIGS. 2A and 2C, the cover plate 208 covers the base block 202, and edge of the opening 2082 of the cover plate 208 cooperates with the first operating slot 2022 and the second operating slot 20210, so that the first operating slot 2022 is fully closed, thereby improving the sliding stability of the slider 204. This can be best seen in FIG. 2C, where an edge of the opening of the cover plate 208 is located to the right of, and at the same height and opposite to, the top part of the first slide rail 20221; the gap between them forms an upper part of the first operating slot 2022, so that the upper part of the first operating slot 2022 becomes enclosed by the edge of the cover plate 208. As seen in FIG. 2C, the lower part of the first operating slot 2022 is enclosed by the first slide rail 20221 and the second slide rail 20222. The slider 204 and the second operating component 210 are partially exposed from the cover plate for user operation. The opening 2082 on the cover plate 208 should meet relevant industry standards, and the size of the opening 2082 will limit the width of the slider 204.

In other embodiments, the upright portion 2062 may also serve as a stopper for the opening 2082 of the cover plate 208. The base block 202 stops (limits the position of) the cover plate 208 based on the protruding sidewalls 2028 (in conjunction with the upright portion 2062). The base block 202 achieves the assembly alignment of the base block 202 and the cover plate 208 via the protruding sidewalls 2028 and the opening 2082 of the cover plate 208.

In some embodiments, the load control device 200 further includes faceplate screws 212, which are used to fix the faceplate to ensure the stability and safety of the faceplate. The faceplate screws 212 may also correct the assembly error between the mating holes of the base block to achieve a tight affixing effect. In some embodiments, the load control device 200 also includes a grounding frame 214, which is configured to couple the metal parts of the device to the ground to prevent risks of electric shock and provide electromagnetic shielding to reduce electromagnetic interference. In some embodiments, the load control device 200 also includes a printed circuit board (PCBA) 216. The printed circuit board (PCBA) 216 is used to firmly connect various electronic components together to form a complete circuit system and provide signal transmission and power supply of the device. In some embodiments, the load control device 200 also includes a base frame 218 for fixing and supporting the entire device, and the device may be installed on a wall, a desktop or other desired assembly location through the base frame. In some embodiments, the load control device 200 further includes components such as a spring 220, a movable contact plate assembly 222, fixing screws 224, a grounding screw 226 and/or a wire pressing plate 228, which have similar functions to the corresponding components in conventional load control device and are not described in detail here.

It is worth mentioning that the present disclosure is particularly suitable for devices in which the first operating slot and the second operating slot are adjacent to each other, such as a sliding dimmer with a toggle switch. Because the opening width of the faceplate needs to meet relevant industry standards (standard size), when the dimmer includes a toggle switch, the width of the slide groove is correspondingly small, and the width of the slider is small, so it is inconvenient for users to operate. Under the condition of meeting the relevant industry standards for the faceplate opening, the device according to embodiments of the present invention may increase the size of the slider head within a certain range without affecting the normal use of the device, thereby improving the convenience of user operation.

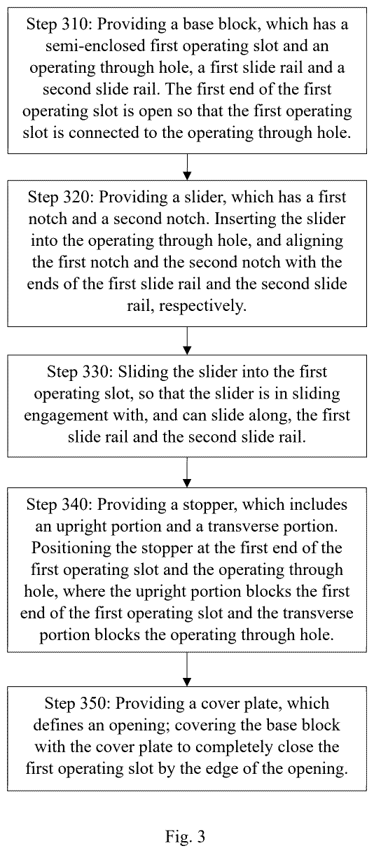

As shown in FIG. 3, another embodiment of the present invention provides an assembly method 300 of a load control device. This embodiment is an assembly method for the load control device 200 described above, and the assembly method 300 includes the following steps:

Step 310, providing a base block 202. The base block 202 has a semi-enclosed first operating slot 2022 and an operating through hole 2024. A first slide rail 20221 and a second slide rail 20222 are provided for the first operating slot 2022. The first end of the first operating slot 2022 is open so that the first operating slot 2022 is connected to the operating through hole 2024.

Step 320, providing a slider 204. The slider 204 has a first notch 2044 and a second notch 2046. The slider 204 is then inserted into the operating through hole 2024, and the first notch 2044 and the second notch 2046 are aligned with the ends of the first slide rail 20221 and the second slide rail 20222, respectively.

Step 330, sliding the slider 204 into the first operating slot 2022, so that the slider 204 is in sliding engagement with, and can slide along, the first slide rail 20221 and the second slide rail 20222.

In some embodiments, the assembly method 300 further includes: step 340, providing a stopper 206, which includes an upright portion 2062 and a transverse portion 2064, and positioning the stopper 206 at the first end of the first operating slot 2022 and the operating through hole 2024, wherein the upright portion 2062 blocks the first end of the first operating slot 2022, and the transverse portion 2064 blocks the operating through hole 2024.

In some embodiments, the assembly method 300 further includes: step 350, providing a cover plate 208, wherein the cover plate 208 defines an opening 2082, and covering the base block 202 with the cover plate 2082 to completely close the first operating slot 2022 by the edge of the opening 2082.

In this embodiment, the assembly process of the load control device 200 is different from that of a traditional device that uses an interference fit structure. It does not require a large force to be applied, which effectively reduces the difficulty of device assembly. In addition, the slider 204 may be assembled on the base block 202 without pressing it through the operating through hole 2024, avoiding deformation or wear of the material during the assembly process and improving the service life of the material. In addition, the structural design of the load control device 200 may reduce the restriction of the width of the slide groove on the width of the slider. Therefore, the width of the slider may be reasonably increased according to actual needs to facilitate user operation. In addition, the S shape of the slide groove and the slider may reduce the connectivity between the outside and the inside of the device. The slot of the slide groove is small, which may effectively prevent dust and other impurities from entering the inside of the device through the slot of the slide groove, thereby improving the safety performance of the device.

The assembly method of the load control device of this embodiment is similar to the implementation method of the load control device of the previous embodiment, so it will not be repeated here.

Embodiments of the present invention are described above. It will be apparent to those skilled in the art that various modifications may be made without departing from the spirit or scope of the invention. While the operation principles of the various embodiments are described, various structures, arrangements, proportions, devices, materials and components may be modified to adapt to particular environments or application requirements without departing from the spirit or scope of the invention. Such modifications of other modifications are within the scope of the present invention. Thus, the above descriptions do not limit the scope of the invention. While the advantages of various embodiments and the solutions to various technical problems are described, the advantages and solutions and any considerations that lead to these advantages or solutions, or other variations of solutions may not be critical, necessarily or inherent. Terms such as “include” or variations of such terms used in the above disclosure should be interpreted as being non-exclusive. The process, method, article of manufacture or apparatus that includes any listed elements may include not only these elements, but other elements not specifically listed or outside of these process, method, article of manufacture or apparatus. Further, terms such as “couple” or variations of such terms used in the above disclosure should be interpreted to include physical coupling, electrical coupling, magnetic coupling, optical coupling, communicative coupling, functional coupling and/or any other form of coupling.

It will be apparent to those skilled in the art that various modifications may be made to the above described embodiments without departing from the spirit or scope of the invention. Thus, it is intended that the scope of the invention is defined by the appended claims.

1. A load control device, comprising:
a base block; and
a first operating component, arranged on the base block, configured to adjust an operation parameter of an electrical load;
wherein the base block includes a slide groove and an operating through hole, wherein a first end of the slide groove is selectively opened to connect the slide groove with the operating through hole,
wherein the first operating component includes a slider, slidably engaged with the slide groove, wherein when the slide groove is connected with the operating through hole, the slider is moveable from the operating through hole to the slide groove to assemble the slider in the slide groove.

2. The load control device of claim 1, further comprising:
a stopper, detachably connected to the base block, configured to block the first end of the slide groove and the operating through hole.

3. The load control device of claim 2, wherein the stopper includes:
an upright portion, configured to block the first end of the slide groove; and
a transverse portion, connected to the upright portion and arranged at an angle relative to the upright portion, configured to block the operating through hole.

4. The load control device of claim 3, wherein the transverse portion includes contactable areas configured to provide operating positions for handling the stopper during assembly.

5. The load control device of claim 1, wherein the slide groove includes a first slide rail and a second slide rail, respectively arranged at different heights;
wherein the slider has an S shape, and includes a first notch and a second notch arranged at different heights and opposite to each other, wherein the first notch is configured to cooperate with the first slide rail and the second notch is configured to cooperate with the second slide rail.

6. The load control device of claim 5, wherein the first operating component further includes a sliding rheostat, wherein a lower end of the slider includes a third notch configured to cooperate with a sliding piece of the sliding rheostat.

7. The load control device of claim 1, wherein the base block includes protruding sidewalls extending upwardly, wherein the slide groove is a semi-enclosed first operating slot formed on one side of one protruding sidewalls.

8. The load control device of claim 7, wherein the protruding sidewalls form a fully enclosed second operating slot located adjacent to the first operating slot;
wherein the load control device further comprises a second operating component, disposed in the second operating slot and configured to control a second operation parameter of the electrical load.

9. The load control device of claim 1, further comprising a cover plate, the cover plate defining an opening, wherein the cover plate covers the base block and fully closes the first operating slot by an edge of the opening.

10. An assembly method for assembling a load control device, comprising:
providing a base block, the base block including a semi-enclosed first operating slot and an operating through hole, a first slide rail and a second slide rail adjacent the first operating slot, wherein a first end of the first operating slot is open so that the first operating slot is connected to the operating through hole;
providing a slider, the slider including a first notch and a second notch;
inserting the slider into the operating through hole and aligning the first notch and the second notch respectively with ends of the first slide rail and the second slide rail; and
sliding the slider into the first operating slot, wherein the slider is in sliding engagement with and is slidable along the first slide rail and the second slide rail.

11. The assembly method of claim 10, further comprising:
providing a stopper, the stopper including an upright portion and a transverse portion, and positioning the stopper to block the first end of the first operating slot and the operating through hole, wherein the upright portion blocks the first end of the first operating slot and the transverse portion blocks the operating through hole.

12. The assembly method of claim 10, further comprising:
providing a cover plate, wherein the cover plate defines an opening, and covering the base block with the cover plate to completely close the first operating slot by an edge of the opening.
